(19) United States
(12) Patent Application Publication
(10) Pub. No.: US 2014/0084327 A1
(43) Pub. Date: Mar. 27, 2014

(54) LIGHT-EMITTING DEVICE

(71) Applicant: EPISTAR CORPORATION, Hsinchu (TW)

(72) Inventors: Yu-Chen YANG, Hsinchu (TW); Chih-Nan LIN, Hsinchu (TW); Jung-Tsung WU, Hsinchu (TW); Chien-Fu SHEN, Hsinchu (TW)

(73) Assignee: EPISTAR CORPORATION, Hsinchu (TW)

(21) Appl. No.: 14/019,303

(22) Filed: Sep. 5, 2013

(30) Foreign Application Priority Data
Sep. 27, 2012 (TW) 101135745

(51) Int. Cl. H01L 33/62

(52) U.S. Cl. CPC H01L 33/62
USPC 257/99

(57) ABSTRACT

A light-emitting device comprises: a substrate having a first side and a second side opposite to the first side; a light-emitting stack disposed on the first side and emitting a light having a main wavelength of λ nm; wherein the substrate comprises a first surface on the first side, the first surface comprising a first pattern arranged with a first period, the first pattern comprising a second pattern arranged with a second period; and the first period is greater than 6λ, and the second period is smaller than λ nm.

### RELATED APPLICATION

This application claims priority from previously filed Taiwan Patent Application No. 101135745 filed on Sep. 27, 2012, entitled as “Light-emitting device”, and the entire contents of which are hereby incorporated by reference herein in its entirety.

### BACKGROUND

1. Technical Field

The present disclosure relates to a light-emitting device and in particular to a light-emitting device having a substrate comprising a first pattern and a second pattern.

2. Description of the Related Art

The light-emitting diodes (LEDs) of the solid-state lighting elements have the characteristics of the low power consumption, low heat generation, long operational life, shockproof, small volume, quick response and good opto-electrical property like light emission with a stable wavelength, so the LEDs have been widely used in household appliances, indicator light of instruments, and opto-electrical products, etc. However, how to improve the light extraction efficiency of the light-emitting device is an important issue in this art.

Besides, light-emitting diodes can be further combined with a sub-mount to form a light emitting device, such as a bulb. The light-emitting device comprises a sub-mount with circuit; a solder on the sub-mount fixing the light-emitting diode on the sub-mount and electrically connecting the base of the light-emitting diode and the circuit of the sub-mount; and an electrical connection structure electrically connecting the electrode pad of the light-emitting diode and the circuit of the sub-mount; wherein the above sub-mount can be a lead frame or a large size mounting substrate in convenience of designing circuit of the light-emitting device and improving its heat dissipation.

### SUMMARY OF THE DISCLOSURE

The present disclosure provides a light-emitting device. The light-emitting device comprises: a substrate having a first side and a second side opposite to the first side and a light-emitting stack on the first side and emitting a light with a main wavelength of λ nm. The substrate comprises a first surface on the first side. The first surface comprises a first pattern arranged with a first period; and the first pattern comprises a second pattern arranged with a second period. Wherein the first period is greater than 6λλnm and the second period is smaller than λ nm.

### BRIEF DESCRIPTION OF THE DRAWINGS

FIG. 1A shows a cross-sectional view of a light-emitting device in accordance with the first embodiment of the present disclosure.

FIG. 1B shows a partial enlarged drawing of the first surface of the substrate in FIG. 1A.

FIG. 2A shows a cross-sectional view of a light-emitting device in accordance with the second embodiment of the present disclosure.

FIG. 2B shows a partial enlarged drawing of the first surface of the substrate in FIG. 2A.

FIG. 2C shows a partial enlarged drawing of the first surface of the substrate in FIG. 2A.

FIG. 3 shows a cross-sectional view of a light-emitting device in accordance with the third embodiment of the present disclosure.

FIG. 4A shows a cross-sectional view of a light-emitting device in accordance with the fourth embodiment of the present disclosure.

FIG. 4B shows a partial enlarged drawing of the first surface of the substrate in FIG. 4A.

FIG. 5A shows a cross-sectional view of a light-emitting device in accordance with the fourth embodiment of the present disclosure.

FIG. 5B shows a partial enlarged drawing of the first surface of the substrate in FIG. 5A.

FIGS. 6A-6G show cross-sectional views of a method of manufacturing a light-emitting device in accordance with the second embodiment of the present disclosure.

FIGS. 7A-7I show cross-sectional views of another method of manufacturing a light-emitting device in accordance with the second embodiment of the present disclosure.

### DETAILED DESCRIPTION OF THE EMBODIMENTS

The drawings illustrate the embodiments of the application and, together with the description, serve to illustrate the principles of the application. To better and concisely explain the disclosure, the same name or the same reference number given or appeared in different paragraphs or figures along the specification should has the same or equivalent meanings while it is once defined anywhere of the disclosure. It is noted that the elements not drawn or described in the figure can be included in the present application by the skilled person in the art.

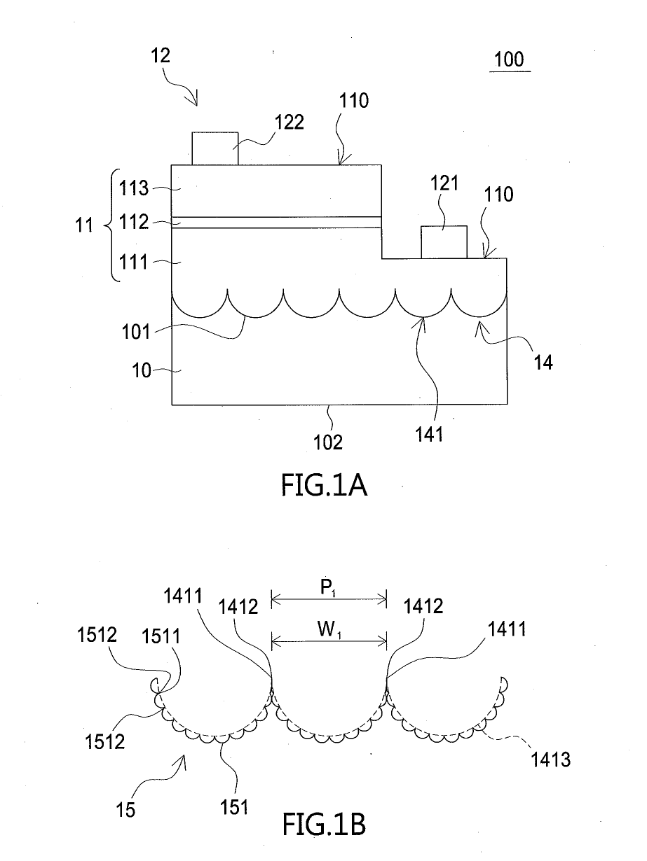

FIG. 1A shows a cross-sectional view of a light-emitting device 100 in accordance with the first embodiment of the present disclosure. The light-emitting device 100 comprises a substrate 10; a light-emitting stack 11 formed on the substrate 10 and an electrode unit 12 formed on the light-emitting stack 11. The substrate 10 has a first surface 101 on the first side and a surface 102 on the second side. The light-emitting stack 11 is formed on the first surface 101 of the substrate 10 and the light-emitting stack 11 has a third surface 110 opposite to the substrate 10. The light-emitting stack 11 emits a light having a main wavelength of λ nm. Besides, the light-emitting stack 11 emits a light comprising a first light field passing through the side of the substrate 10 and a second light field passing through the side of the electrode unit 12, wherein the light intensity of the first light field is larger than that of the second light field. The light-emitting stack 11 comprises a first type semiconductor layer 111, an active layer 112, and a second type semiconductor layer 113. The electrode unit 12 is formed on the third surface 110. The electrode unit 12 comprises a first electrode 121 formed on the first type semiconductor layer 111 and a second electrode 122 formed on the second type semiconductor layer 113 and first electrode 121 and the second electrode 122 are formed on the same side of the light-emitting stack 11. In one embodiment, a reflective layer (not shown in the figure) can be formed on the third surface 110 to reflect light emitted from the light-emitting stack 11 to a direction toward the second side of the substrate 10 to leave the light-emitting stack 11.

The first surface 101 of the substrate 10 comprises a first pattern 14 arranged with a first period. The first pattern 14 comprises a plurality of pattern units 141 depressed from the first side of the substrate 10 to the second side of the substrate 10 (depressed toward inside of the substrate 10). The cross-sectional view of the pattern units 141 can be v-shape, semicircular, arc, and polygon. FIG. 1B shows a partial enlarged drawing of the first pattern 14 in FIG. 1A. In this embodiment, a cross-sectional view of the pattern units 141 is an arc and each of the pattern units comprises a first end 1411, a second end 1412, and an edge 1413 connecting the first end 1411 and the second end 1412. Pattern units 141 are arranged closely to each other, so that the first end 1411 of a pattern unit 141 and the second end 1412 of an adjacent pattern unit 141 are connected to each other. As shown in FIG. 1B, the first pattern 14 comprises a second pattern 15 arranged with a second period. The second pattern 15 comprises two adjacent concaves 151 formed on a pattern unit 141. In one embodiment, the concaves 151 are formed on each pattern unit 141 so that every edge 1413 of each pattern unit 141 comprises a concave 151. Optionally, some of the pattern units 141 comprise second patterns 15 but some of pattern units 141 do not. The depressing direction of the concaves 151 is substantially in a direction from the first side of the substrate 10 to the second side of the substrate 10 (depressed toward inside of the substrate 10). The cross-sectional views of the concaves 151 of the second pattern 15 can be v-shape, semicircular, arc, and polygon. In this embodiment, the cross-sectional view of the second pattern 15 is also an arc and a cross-sectional view of each concave 151 comprises a first end 1511 and a second end 1512. The concaves 151 are arranged closely such that the first end 1511 of a concave 151 is connected to the second end 1512 of another adjacent concave 151. Optionally, concaves 151 are not arranged closely. That is, the first end 1511 of a concave 151 is not directly connected to the second end 1512 of another adjacent concave 151 and a space between them is in a range between 0100 nm. In one embodiment, the first pattern 14 has a width (W₁) larger than 6λ nm and a first period P₁; and the second pattern 15 has a width (W₂) less than λ nm and a second period P₂. While the first pattern 14 and the second pattern 15 are both arranged closely, W₁=P₁ and W₂=P₂. In one embodiment, while the ratio of P2/P1 is greater than 1/15, the light emitted from the light-emitting stack 11 is effectively passing through the second side of the substrate 10. Besides, when a ratio of height and width of the second pattern 15 is larger than 1.5, the light emitted from the light-emitting stack 11 also effectively passes through the second side of the substrate 10. Furthermore, it is benefit for light emitted from the light-emitting stack 11 passing through the second side of the substrate 10 by forming a first pattern 14 and a second pattern 15 on the first surface 101 of the substrate 10.

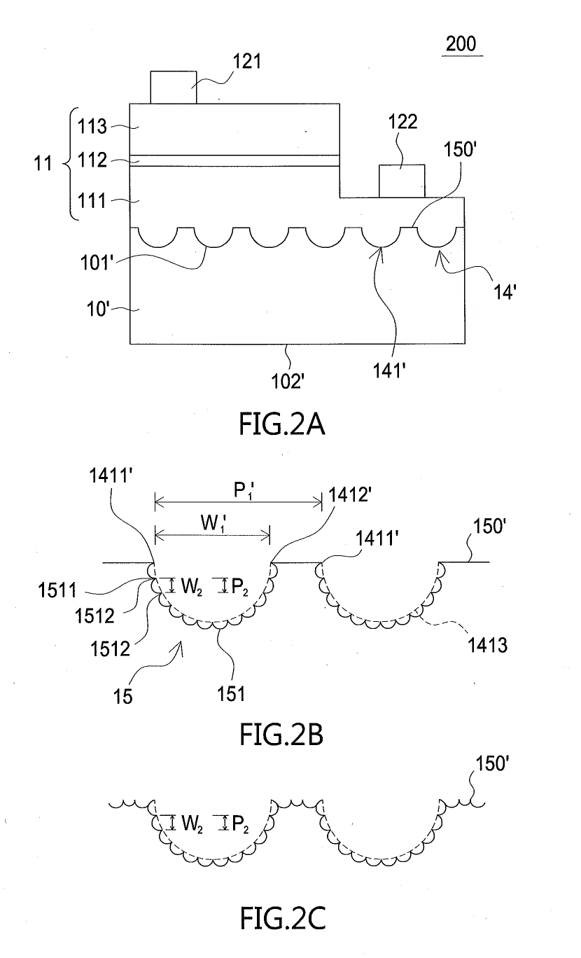

FIG. 2 shows a schematic view of the light-emitting device 200 in accordance with the second embodiment of the present disclosure. The light-emitting device 200 of the second embodiment has a similar structure with the first light-emitting device 100. The first surface 101′ of the substrate 10′ comprises a first pattern 14′ arranged with a first period. The first pattern 14′ comprises a plurality pattern unit 141′ depressed from the first side of the substrate 10′ to the second side of the substrate 10′ and a middle area 150′. The cross-sectional views of the pattern unit 141′ can be v-shape, semicircular, arc, and polygon. FIG. 2B shows a partial enlarged drawing of the first pattern 14′ in FIG. 2A. In this embodiment, the cross-sectional view of the pattern unit 141′ is an arc and each pattern unit 141′ comprises a first end 1411′, a second end 1412′ and an edge 1413′ connecting the first end 1411′ and the second end 1412′. In this embodiment, a distance between the first end 1411′ of the pattern unit 141′ and a second end 1412′ of another adjacent pattern unit 141′ is less than 1500 nm which means the width of the middle area 150′ is less than 1500 nm. As shown in FIG. 2B, the first pattern 14′ comprises a second pattern 15 arranged with a second period. The second pattern 15 comprises two adjacent concaves 151 on the pattern unit 141′. In one embodiment, the concave 151 is formed on whole pattern unit 141′. That is, every edge 1413 of the pattern units 141′ comprises concaves 151. The direction of the concaves 151 depressing is substantially from the first side of the substrate 10′ to the second side of the substrate 10′ (depressing in a direction toward the inside of the substrate 10′). The cross-sectional views of the concaves 151 of the second pattern 15 can be v-shape, semicircular, arc, and polygon. In this embodiment, the cross-sectional view of the second pattern 15 is an arc and comprises a first end 1511 and a second end 1512. Every concave 151 is arranged closely such that the first end 1511 of a concave 151 is directly connected to the second end 1512 of another adjacent concave 151. Optionally, the concaves 151 are not arranged closely. That is, the first end 1511 of a concave 151 is not directly connected to the second end 1512 of an adjacent concave 151 and a distance between is in a range of 0˜100 nm. In this embodiment, a first pattern 14′ has a width W₁′ larger than 6λ nm and a first period P₁′ and a second pattern 15′ has a width W₂′ less than λ nm and a period P₂′. Since the first pattern 14′ has a middle area 150′, W₁′<P₁′; the second patterns 15 are arranged closely thus W₂′=P₂′. In another embodiment shown in FIG. 2C, the middle area 150′ of the first pattern 14′ comprises a second pattern 15′. In one embodiment, while the ratio of P₂/P₁> 1/15, light emitted from the light-emitting stack effectively passes through the second side of the substrate 10′.

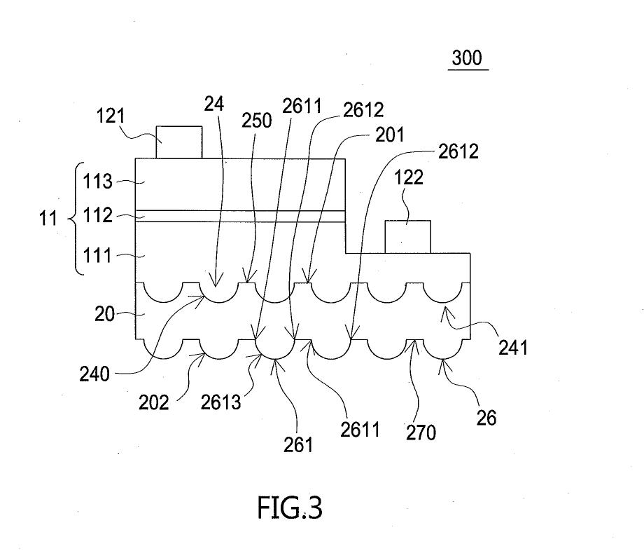

FIG. 3 shows a schematic view of a light-emitting device 300 in accordance with the third embodiment of the present disclosure. The light-emitting device 300 in accordance with the third embodiment has a similar structure to the light-emitting device 200 in accordance with the second embodiment. The second surface 202 of the substrate 20 comprises a third pattern 26 arranged with a third period. The third pattern 26 comprises a pattern unit 261 and a middle area 270. The cross-sectional views of a pattern unit 261 can be v-shape, semicircular, arc, and polygon. In this embodiment, the cross-sectional view of the pattern unit 261 is an arc and each pattern unit 261 comprises a first end 2611, a second end 2612, and an edge 2613 connecting the first end 2611 and the second end 2612. The distance between the first end 2611 of a pattern unit 261 and the second end 2612 of another adjacent pattern unit 261 is less than 1500 nm which means the width of the middle area 270 is less than 1500 nm. In this embodiment, the pattern unit 241 of the first pattern 24 and the pattern unit 261 of the third pattern 26 are formed on corresponding locations; the middle area 250 of the first pattern 24 is formed on a location corresponding to the location of the middle area 270 of the third pattern 26. Or, the pattern unit 241 of the first pattern 24 and the middle area 270 of the third pattern 26 are formed on corresponding locations (not shown in the figure), that is, the pattern unit 241 and the pattern unit 261 are arranged alternately. In one embodiment, the first pattern 24 and/or the third pattern 26 comprises the second pattern 15.

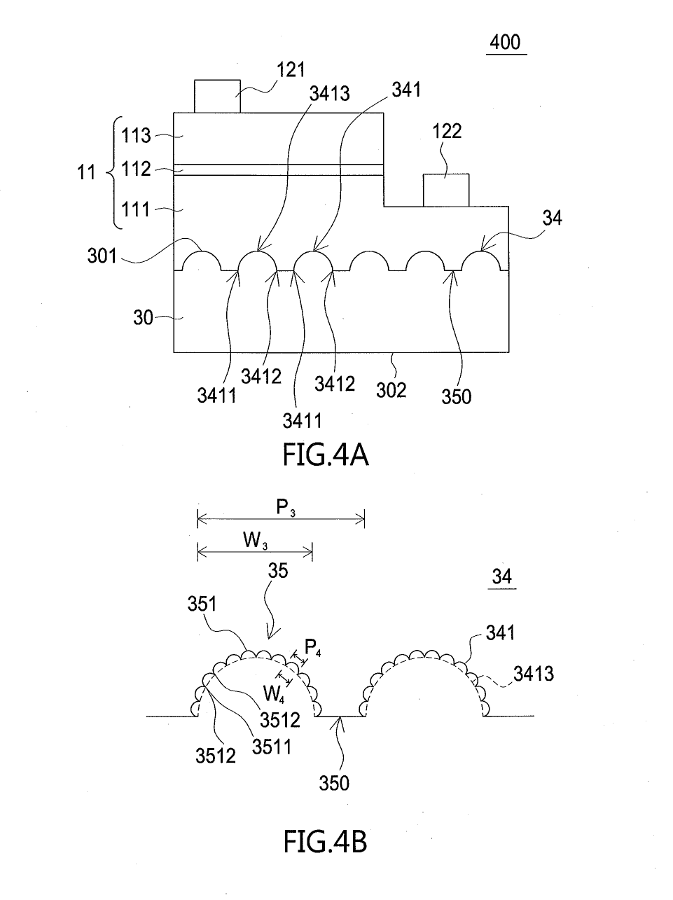

FIG. 4A shows a schematic view of the light-emitting device 400 in accordance with the fourth embodiment of the present disclosure. The light-emitting device 400 in accordance with the fourth embodiment has a similar structure compared with the light-emitting device 100 in accordance with the first embodiment. The light-emitting stack 11 is formed on the first surface 301 of the substrate 30. The first surface 301 of the substrate 30 comprises a first pattern 34 arranged with a first period. The first pattern 34 comprises a plurality of pattern units 341 protruded from the first surface 301 of the substrate outward of the substrate 30 (protruded from the second side of the substrate 30 toward the first side of the substrate 30), and a middle area 350. The cross-sectional views of the pattern unit 341 can be v-shape, semicircular, arc, and polygon. In this embodiment, the cross-sectional view of the pattern unit 341 is an arc comprising a first end 3411, a second end 3412 and an edge 3413 connecting the first end 3411 and the second end 3412. In this embodiment, the distance between a first end 3411 of a pattern unit 3411 and a second end 3412 of another adjacent pattern unit 341 is less than 1500 nm which means the width of the middle area 350 is less than 1500 nm. In one embodiment, the first patterns 34 are arranged closely. That is, a first end 3411 of a pattern unit 341 is directly connected to the second end 3412 of another adjacent pattern unit 341. FIG. 4B shows a partial enlarged drawing of the first pattern 34 in FIG. 4A. As shown in FIG. 4B, the first pattern 34 comprises a second pattern 35 arranged with a second period. The second pattern 35 comprises two adjacent protrusion parts 351 formed on the pattern unit 341. In one embodiment, the protrusion parts 351 are formed on whole pattern unit 341 which means all the edges 3413 of the pattern unit 341 comprise protrusion parts 351. Optionally, some of the pattern units 341 comprise the second pattern 35 but some of the pattern units 341 do not. The protruded direction of the protrusion part 351 is substantially from the second side of the substrate 10 toward the first side of the substrate 10 (protruded outward from the substrate). The cross-sectional views of the protrusion part 351 of the second pattern 35 can be v-shape, semicircular, arc, and polygon. In this embodiment, the cross-sectional views of the second pattern 35 are also an arc and the cross-sectional views of the protrusion part 351 comprise a first end 3511 and a second end 3512. The protrusion parts 351 are arranged closely, which means a first end 3511 of a pattern unit 351 is directly connected to the second end 3512 of another adjacent pattern unit 351. Alternately, protrusion parts 351 can be arranged non closely-arranged. Such that, a first end 3511 of a protrusion part 351 is not directly connected to the second end 3512 of an adjacent protrusion part 351 and a distance between is in a range of 1˜100 nm. In this embodiment, a first pattern 34 has a width W₃ larger than 6λ nm and a first period P₃. The second pattern 35 has a width W₄ less than λ nm and a period P₄. Because the first pattern 34 comprises a middle area 350 thus W₃<P₃; and the second patterns are arranged closely thus W₄=P₄. In another embodiment, as shown in FIG. 2C, the middle area 350 of the first pattern 34 comprises a second pattern 15. In one embodiment, while the ratio of P₄/P₃> 1/15, light emitted from the light-emitting stack 11 effectively passes through the second side of the substrate 10′. Moreover, it is helpful for light emitted from the light-emitting stack injecting toward the second surface 302 of the substrate 30 by forming a first pattern 34 and a second pattern 35 on the first surface 301 of the substrate 30.

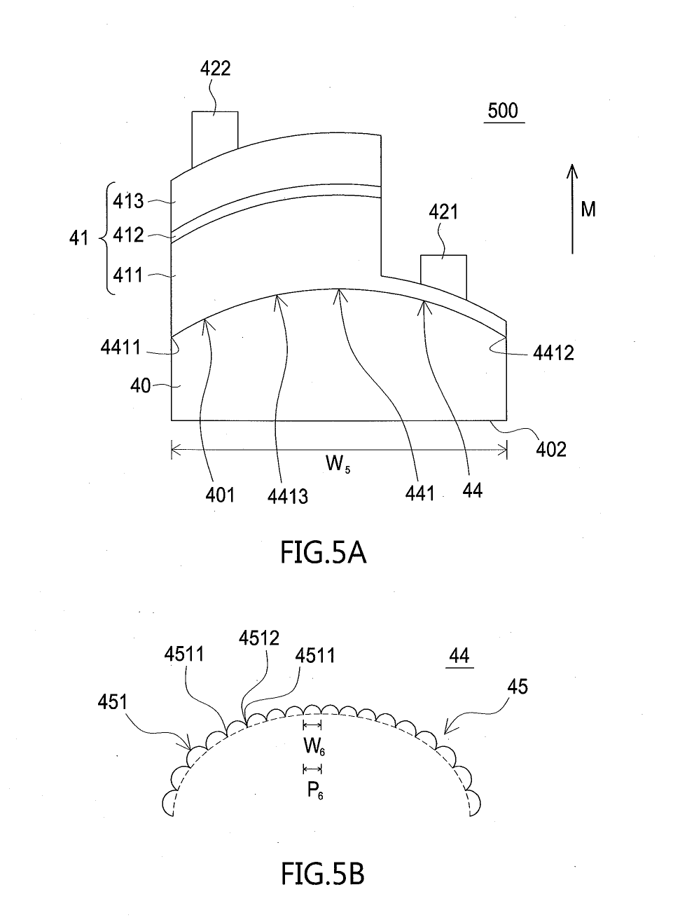

FIG. 5A shows a schematic view of a light-emitting device 500 in accordance with the fifth embodiment of the present disclosure. The substrate 40 comprises a first surface 401 and a second surface 402 opposite to the first surface 401. The first surface 401 comprises a first pattern 44 comprising a protrusion region 441 wherein the protrusion region 441 is protruded from the second surface 402 toward the first surface 401 (protruded outward of the substrate 40). The cross-sectional view of the protrusion region 441 comprises a first end 4411, a second end 4412, and an edge 4413 connecting the first end 4411 and the second end 4412. The distance between the first end 4411 and the second end 4412 is not larger than the width W₅ of the second surface 402. In this embodiment, the distance between the first end 4411 and the second end 4412 equals to the width W₅ of the second surface 402. The light-emitting stack 41 formed on the first surface 401 emits a light having a wavelength λ nm. Because the first surface 401 is an arc, the light-emitting stack 41 has an arc structure. The light emitting stack 41 comprises a first type semiconductor layer 411, an active layer 412, and a second type semiconductor layer 413. The first electrode 421 is formed on the first type semiconductor layer 411 and the second electrode 422 is formed on the second type semiconductor layer 413. The cross-sectional view of the first pattern 44 can be v-shape, semicircular, arc, and polygon. FIG. 5B shows a partial enlarged drawing of the first pattern 44 in FIG. 5A. The first pattern 44 comprises a second pattern 45 arranged with a second period. The second pattern 45 comprises two adjacent protrusion parts 451 formed on the protrusion region 441. In one embodiment, the protrusion parts 451 are formed on whole protrusion region 441 which means the edges 4413 of the protrusion region 441 comprise protrusion parts 451. The protrusion parts 451 are protruded from the second surface 402 of the substrate 40 toward the first surface 401 of the substrate 40 (protruded outward of the substrate 40). The cross-sectional view of the protrusion part 451 of the second pattern 45 can be v-shape, semicircular, arc, and polygon. In this embodiment, the cross-sectional views of the second pattern 45 are also an arc and the cross-sectional view of the protrusion part 451 comprises a first end 4511 and a second end 4512. The protrusion parts 451 are arranged closely, which means the first end 4511 of a protrusion part 451 is directly connected to the second end 4512 of an adjacent protrusion part 451. In this embodiment, the first pattern 44 has a width W₅ larger than 6λ nm. The second pattern 45 has a width W₆ less than λ nm and a period P₆. Since the second patterns 45 are arranged closely, so W₆=P₆.

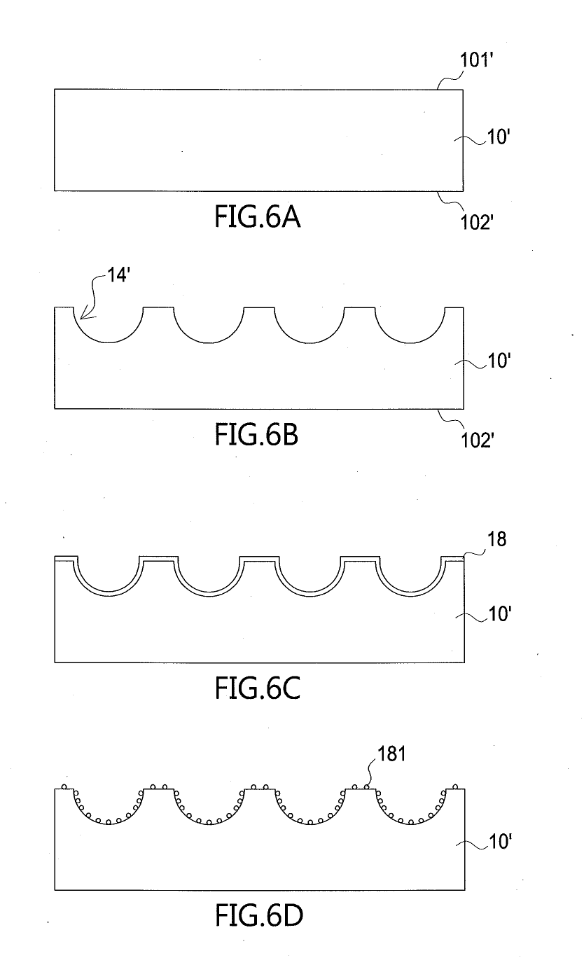

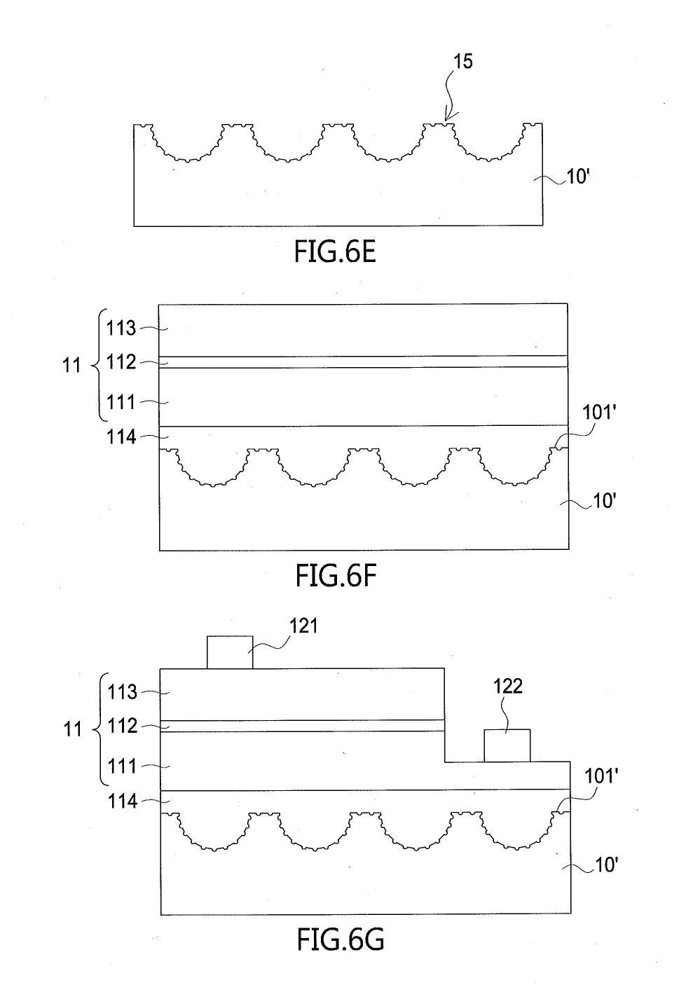

FIGS. 6A-6G show cross-sectional views of a method of manufacturing a light-emitting device in accordance with the second embodiment of the present disclosure. A substrate 10′ which has a first surface 101′ and a second surface 102′ is provided. An etching process is applied to the first surface 101′ to form a first pattern 14′ with a first period on the first surface 101′. A metal layer 18 is formed on the first pattern 14′, wherein the metal layer 18 comprises silver, gold, nickel or platinum and the metal layer 18 has a thickness of about 100-300 Å. Then, an alloy process under a high temperature is applied to the metal layer 18 such that the metal layer 18 is formed into nano-balls. An etching process using nano-balls as a mask is applied to the first pattern 14′ wherein the etching process comprises dry etching process such as inductively coupled plasma (ICP), or wet etching process with phosphoric acid and/or sulfuric acid so the first pattern 14′ has a second pattern 15. Then, a buffer layer 114 is formed on the first surface 101′ and a light-emitting stack 11 is grown on the buffer layer 114 with an epitaxy growing technology such as metal-organic chemical vapor deposition (MOCVD). Then, a part of the second type semiconductor layer 113 and the active layer 112 is removed to expose a part of the first type semiconductor layer 111. Separately growing a first electrode 121 on the first type semiconductor layer 111 and growing a second electrode 122 on the second type semiconductor layer 113.

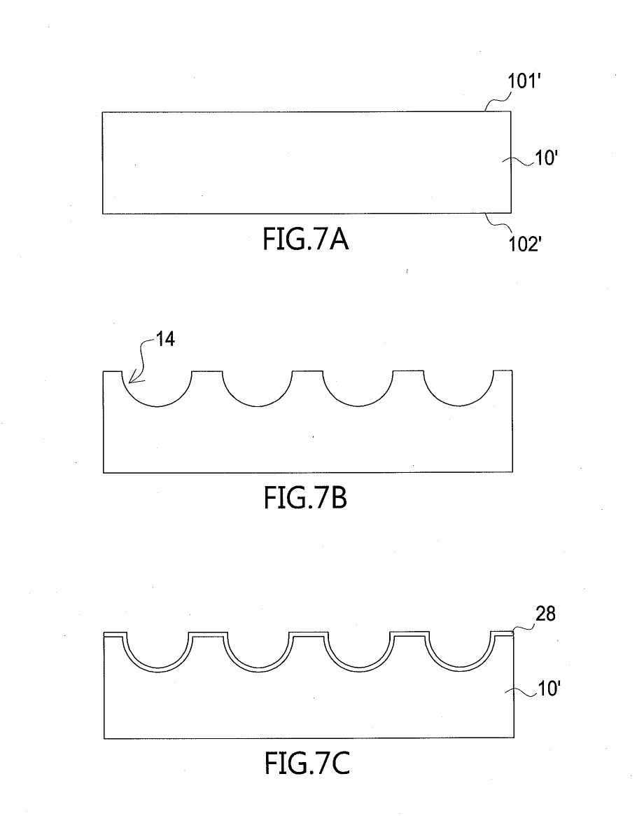

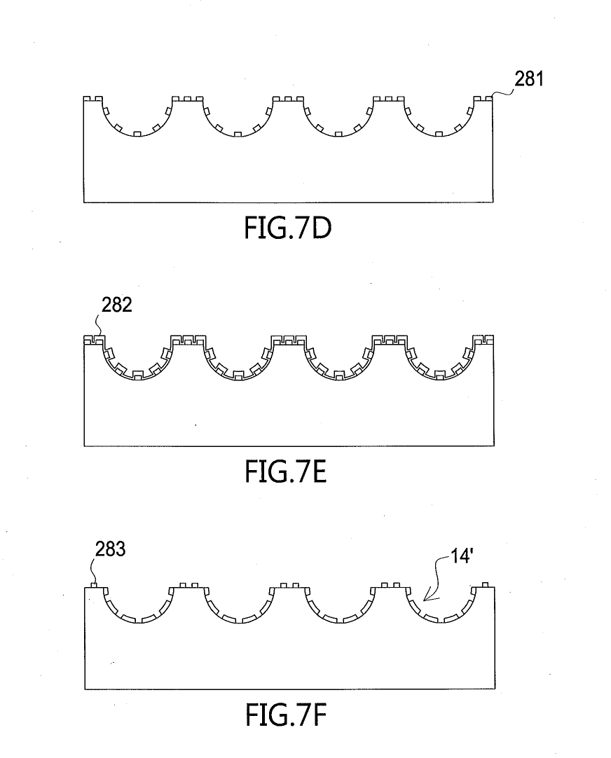

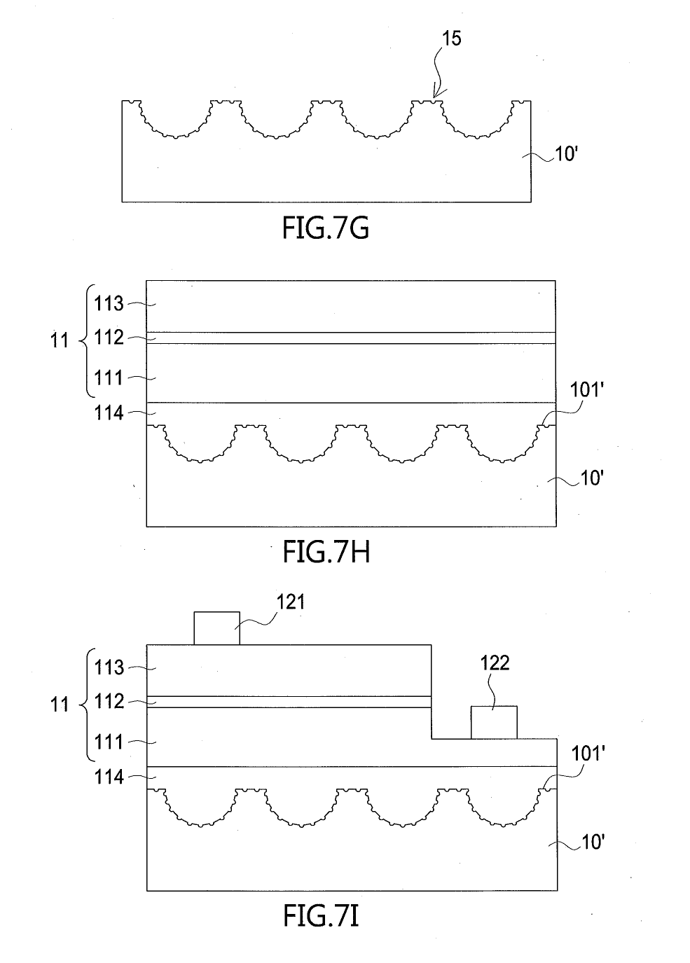

FIGS. 7A-7I show cross-sectional views of a method of manufacturing a light-emitting device in accordance with the second embodiment of the present disclosure. As shown in FIGS. 7A and 7B, a substrate 10′ having a first surface 101′ and a second surface 102′ is provided. An etching process is provided on the first surface 101′ to form a first pattern 14′ arranged with a first period on the first surface 101′. As shown in FIGS. 7C and 7D, a photoresist layer 28 is formed on the first pattern 14′ and a patterned photoresist layer 281 is then formed by a lithography process. As shown in FIG. 7E, a metal layer 282 is formed to cover the patterned photoresist layer 281 wherein the metal layer 282 comprises silver, gold, nickel or platinum and has a thickness of about 100-300 Å. As shown in FIG. 7F, the patterned photoresist layer 281 is removed to form a patterned metal layer 283. An etching process using the patterned metal layer 283 as a mask is applied to the first pattern 14′ wherein the etching process comprises dry etching process such as inductively coupled plasma (ICP) and wet etching process with phosphoric acid and/or sulfuric acid so the first pattern 14′ has a second pattern 15 as shown in FIG. 7G. As shown in FIGS. 7H and 7I, a buffer layer 114 is formed on the first surface 101′ and a light-emitting stack 11 is grown on the buffer layer 114 with an epitaxy growing technology such as metal-organic chemical vapor deposition (MOCVD). A part of the second type semiconductor layer 113 and a part of the active layer 112 is removed to expose the first type semiconductor layer 111. Separately growing a first electrode 121 on the first type semiconductor layer 111 and growing a second electrode 122 on the second type semiconductor layer 113.

The first type semiconductor layer can be an n-type semiconductor layer and the second type semiconductor layer can be a p-type semiconductor layer. The materials of the first type semiconductor layer and the second type semiconductor layer comprise a material selected from a group consisted of AlGaAs, AlGaInP, AlInP and InGaP or a material selected from a group consisted of AlInGaN, InGaN, AlGaN and GaN. Alternatively, the first type semiconductor layer can be a p-type semiconductor layer and the second type semiconductor layer can be an n-type semiconductor layer. The active layer comprises a material selected from a group consisted of AlGaAs, AlInGaP, InGaP and AlInP or a material selected from a group consisted of AlInGaN, InGaN, AlGaN and GaN. The substrate can be gallium arsenide (GaAs) and gallium phosphide (GaP), germanium (Ge), sapphire, glass, diamond, silicon carbide (SiC) and silicon, gallium nitride (GaN), and zinc oxide (ZnO) or other alternative material.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A light-emitting device, comprising:
a substrate having a first side and a second side opposite to the first side; and
a light-emitting stack on the first side and emitting a light with a main wavelength of λ nm;
wherein the substrate comprises a first surface on the first side, and the first surface comprises a first pattern arranged with a first period, and the first pattern comprises a second pattern arranged with a second period; and
wherein the first period is greater than 62λ nm and the second period is smaller than λ nm.

2. The light-emitting device of claim 1, wherein the second pattern has a height and a width, and a ratio between the height and the width is greater than 1.5.

3. The light-emitting device of claim 1, wherein the first pattern comprises a plurality of pattern units depressed from the first side toward the inside of the substrate or protruded outward from the first side of the substrate.

4. The light-emitting device of claim 1, wherein the first pattern comprises a plurality of pattern units depressed from the first side toward the inside of the substrate and a middle area comprising the second pattern.

5. The light-emitting device of claim 1, wherein the second pattern comprises two adjacent protrusion parts or concaves directly connected.

6. The light-emitting device of claim 1, wherein the second pattern comprises a distance between two adjacent protrusion parts or concaves being in a range between 0˜100 nm.

7. The light-emitting device of claim 1, further comprising a first electrode and a second electrode formed on a same side of the light-emitting stack.

8. The light-emitting device of claim 1, further comprising a sub-mount and the light-emitting device is flip-chip bonded to the sub-mount.

9. A light-emitting device, comprising:
a substrate;
a light-emitting stack formed on the substrate; and
an electrode unit formed on the light-emitting stack;
wherein the light-emitting stack emits a first light field passing through one side of the substrate and a second light field passing through the electrode unit; and
wherein a light intensity of the first light field is greater than that of the second light field.

10. The light-emitting device of claim 9, wherein the substrate comprises a surface adjacent to the light-emitting stack, and the surface comprises a first pattern arranged with a first period and the first pattern comprises a second pattern arranged with a second period.
